(19) United States
(12) Patent Application Publication
(10) Pub. No.: US 2004/0125533 A1
(43) Pub. Date: Jul. 1, 2004

(54) ESD PROTECTION DEVICE

(76) Inventors: Tien-Hao Tang, Taipei Hsien (TW); Shiao-Shien Chen, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/248,192

(22) Filed: Dec. 25, 2002

(51) Int. Cl. H01L 29/74

(52) U.S. Cl. 361/173; 257/173

(57) ABSTRACT

An electrostatic discharge (ESD) protection device is composed of Zener diode. The ESD protection device has a Zener diode positioned in a substrate of a semiconductor wafer, a dielectric layer positioned on the substrate, a pad metal positioned on a surface of the dielectric layer above the Zener diode, at least a first contact plug positioned in the dielectric layer and electrically connecting the pad metal and the Zener diode, a passivation layer covering a surface of the semiconductor wafer and exposing a portion of a surface of the pad metal, at least a doped region positioned in the substrate and beyond the Zener diode, at least a power line positioned on the dielectric layer of the semiconductor wafer, and at least a second contact plug electrically connecting the doped region and the power line.

### BACKGROUND OF INVENTION

1. Field of the Invention

The present invention relates to an electrostatic discharge (ESD) protection device composed of a Zener diode, and more particularly, to an ESD protection device combined with a pad.

1. Description of the Prior Art

Electrostatic discharge (ESD) is a common phenomenon in semiconductor processes. The excess current brought by ESD enters an IC via an I/O pin for a very short time and destroys the internal circuitry of the IC. In order to solve the problem, a protection circuit is usually installed between the internal circuitry and the I/O pin. The protection circuit must activate before the pulse of an electrostatic discharge can reach the internal circuitry, so as to instantly eliminate the high voltage of the pulse. Consequently, the destruction caused by ESDis reduced.

The prior art method of preventing electrostatic breakdown caused by electrostatic pulses is using n well-p substrate diodes or MOSFET parasitic diodes as ESD protection devices. Please refer to FIG. 1. FIG. 1 is a cross sectional diagram of a prior art ESD protection circuit composed of a MOS diode. The MOS diode is formed on a p substrate 10. An n well region 11 is formed in a surface layer of the substrate 10, and a p source region 12 and a p drain region 14 are formed in the n well region 11. A gate electrode layer 16 made of polycrystalline silicon is formed on a gate oxide layer 18 over a surface portion of the n well region 11 between the p source region 12 and the p drain region 14, to thus provide a PMOS transistor. A high concentration n+ pickup region 20 is adjacent to the p source region 12, and a common source electrode 22 is formed on the n+ pickup region 20 and the p source region 12.

Also, a p well region 31 is formed in another portion of the surface layer of the p substrate 10, and an n source region 32 and a drain region 34 are formed in the p well region 31. A gate electrode layer 36 made of polycrystalline silicon is formed on a gate oxide layer 38 over a surface portion of the p well region 31 between the n source region 32 and the n drain region 34, to thus provide an NMOS transistor. A high concentration p+ pickup region 40 is adjacent to the n source region 32, and a common source electrode 42 is formed on the p+ pickup region 40 and the n source region 32. A drain electrode 44 that is in contact with both the p drain region 14 of the PMOS transistor and the n drain region 34 of the NMOS transistor is connected to the input and output terminals. The p well region 31 and the n drain region 34 constitute a p well-n drain diode 45, and the p drain region 14 and the n well region 11 constitute a p drain-n well diode 46. These diodes 45, 46 provide protective elements for preventing electrostatic breakdown caused by electrostatic pulses from the input and output terminals.

However, these diodes 45, 46 have high internal resistance, and therefore a large diode area is required for sufficiently absorbing electrostatic pulses from the input and output terminals. Therefore, the prior art method has to use complicated processes to produce the above-mentioned ESD protection device with a complex structure, and the ESD protection device takes up large layout areas.

### SUMMARY OF INVENTION

It is therefore a primary objective of the present invention to provide an ESD protection device composed of Zener diode, which is formed under a pad so as to overcome the problems caused by complex processes and large layout areas.

In a preferred embodiment, the present invention provides an ESD protection device. The ESD protection device comprises a Zener diode positioned in a substrate of a semiconductor wafer. A dielectric layer is positioned on the substrate, and a pad metal is positioned on a surface of the dielectric layer above the Zener diode. At least a first contact plug is positioned in the dielectric layer, and electrically connects the pad metal and the Zener diode. A passivation layer covers a surface of the semiconductor wafer and exposes a portion of a surface of the pad metal. At least a doped region is positioned in the. substrate and beyond the Zener diode. At least a power line is positioned on the dielectric layer of the semiconductor wafer. And, at least a second contact plug electrically connects the doped region and the power line.

The ESD protection device of the present invention directly forms a Zener diode under a pad, so the large layout area occupied by the prior art MOS diode will be saved. As well, the Zener diode is formed by the reverse photo mask of the pad, so as to effectively simplify the semiconductor processes.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a cross-sectional diagram of the structure of a prior art MOS diode.

FIG. 2 to FIG. 5 are cross-sectional diagrams of a process of forming an ESD protection device composed of a Zener diode, according to the present invention.

FIG. 6 is a cross-sectional diagram of the structure of the ESD protection device according the present invention.

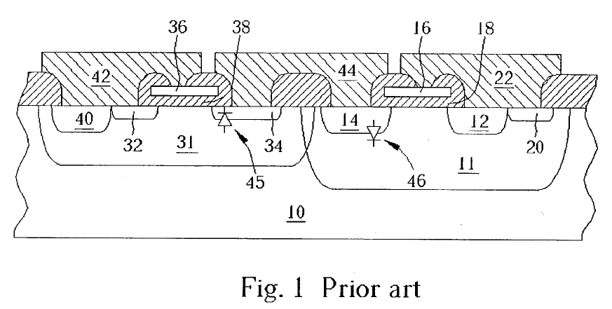

### DETAILED DESCRIPTION

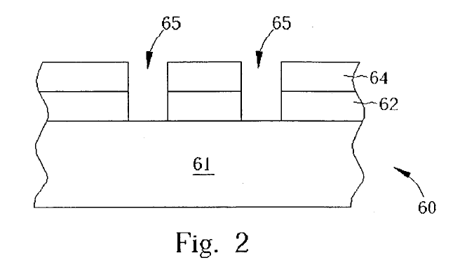

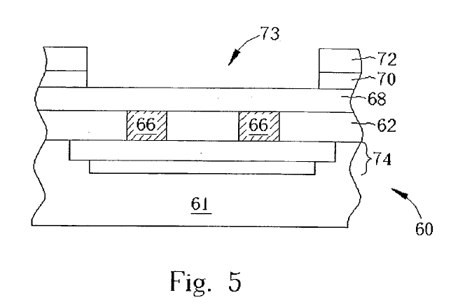

Please refer to FIG. 2 to FIG. 5. FIG. 2 to FIG. 5 are cross-sectional diagrams of a process of forming an ESD protection device composed of Zener diode according to the present invention. As shown in FIG. 2, the ESD protection device is formed on a P-type silicon substrate 61 of a semiconductor wafer 60. The present invention first forms a dielectric layer 62 and a first photoresist layer 64 sequentially on the surface of the semiconductor wafer 60. Then, a photo-etching process (PEP) is used to form a plurality of contact holes 65 in the dielectric layer 62.

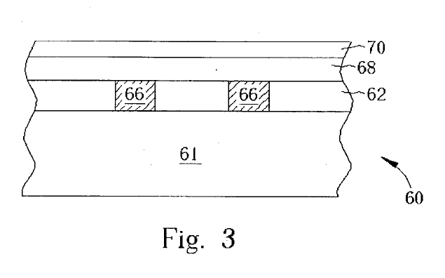

As shown in FIG. 3, after removing the first photoresist layer 64 on the surface of the semiconductor wafer 60, a first metal layer (not shown) is then deposited on the surface of the semiconductor wafer 60 and fills the contact holes 65. A chemical-mechanical polishing (CMP) process or an etching-back process is performed to form a plurality of contact plugs 66. Thereafter, a second metal layer is deposited, and a photo-etching process (PEP) is performed to correspondingly form at least one pad metal 68 on each contact plug 66. Then, a passivation layer 70 is formed on the surface of the semiconductor wafer 60 and covering the pad metal 68. The contact plug 66 and the pad metal 68 can also be formed by a dual damascene process.

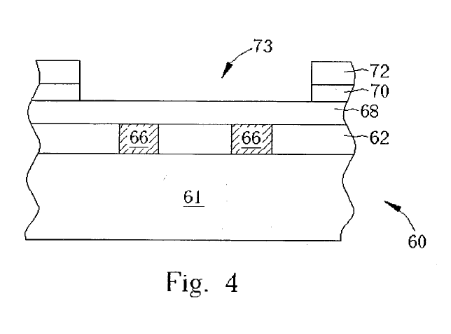

As shown in FIG. 4, a second photoresist layer 72 is formed on the surface of the semiconductor wafer 60, then a photo-etching process (PEP) is performed to define and form a pad opening 73 in the passivation layer 70 above each pad metal 68. First and second ion implantation processes are sequentially performed. The first ion implantation process is an N-type or a P-type ion implantation process, while the second ion implantation process is a P-type or an N-type ion implantation process. Different implant energies or different dopant weights are used to selectively form a Zener diode 74 composed of an upper N-type doped region with a lower P-type doped region or an upper P-type doped region with a lower N-type doped region in the substrate. The dosage of N-type dopant in the Zener diode 74 is about 1E13˜1E14 cm⁻², and the dosage of P-type dopant in the Zener diode 74 is about 1E13˜1E14 cm⁻².

The above-mentioned method of forming an ESD protection device composed of a Zener diode according to the present invention only provides a preferred embodiment. In other words, the first ion implantation process or the second ion implantation process can be also performed before depositing the dielectric layer 62 or before forming each contact hole 65. In another embodiment, one ion implantation process can be performed first, and the other ion implantation process is then performed after forming the pad opening 73 so as to form a Zener diode 74 under the metal pad 68.

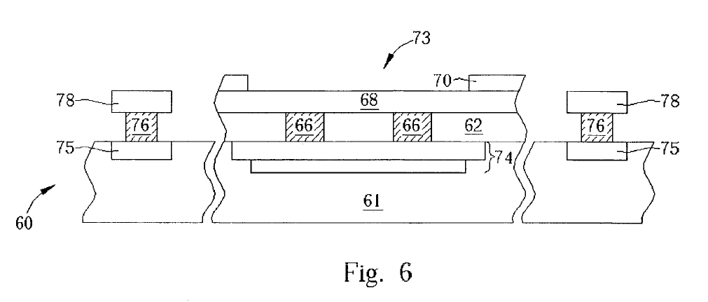

Please refer to FIG. 6. FIG. 6 is a cross-sectional diagram of the structure of the ESD protection device according the present invention. The ESD protection device comprises a Zener diode 74 formed in a P-type silicon substrate 61 of a semiconductor wafer 60. A pad metal 68 is formed on the Zener diode 74, and a dielectric layer 62 is positioned between the pad metal 68 and the Zener diode 74. A plurality of first contact plugs 66 are formed in the dielectric layer 62 for electrically connecting the Zener diode 74 and the pad metal 68. An I/O terminal (not shown) is positioned on the pad metal 68 for receiving imported positive and negative pulses. In addition, a plurality of P-type doped regions 75 are formed in the silicon substrate 61 adjacent to the Zener diode 41, and a plurality of contact plugs 76 are formed above each P-type doped region 75 and used for electrically connecting the power line 78 formed on the semiconductor wafer 60 in sequence.

As a positive pulse is imported via the pad metal 68, the positive pulse will be transmitted to the Zener diode 74 through each contact plug 66. At this time, the Zener diode 74 is in a reverse bias state. The primary feature of Zener diode 74 is that when in a reverse bias state, the input voltage can vary in a certain range and will not affect an almost stable output voltage. Also, as a negative pulse is imported via the pad metal 68, the negative pulse is transmitted to Zener diode 74 through the first contact plug 66. At this time, the Zener diode 74 is in a forward bias state. The Zener diode has a threshold voltage in the forward bias state. Before the negative pulse reaches the threshold voltage, the forward current is almost zero. Hence the purpose of the protection circuit is achieved. The negative pulse is grounded via contact plug 76.

When the ESD protection device of the present invention is formed in an N-type silicon substrate or an N-well, the doped region electrically connected with the contact plug 66 is an N-type doped region, so the above-mentioned operation mode is approximately opposite. Moreover, the silicon substrate in the ESD protection device of the present invention can also be directly connected to ground, so as to save the processes of forming each N-type or P-type doped region, contact plug and power line.

In contrast to the prior art method, the ESD protection device provided by the present invention forms a Zener diode under a pad, so the large layout area occupied by the prior art MOS diode is saved. As well, the Zener diode is formed by the reverse photo mask of the pad so as to effectively simplify the semiconductor processes.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. An electrostatic discharge (ESD) protection device comprising:
a Zener diode positioned in a substrate of a semiconductor wafer;
a dielectric layer positioned on the substrate;
a pad metal positioned on a surface of the dielectric layer above the Zener diode;
at least a first contact plug positioned in the dielectric layer and electrically connecting the pad metal and the Zener diode; and
a passivation layer covering a surface of the semiconductor wafer and exposing a portion of a surface of the pad metal.

2. The ESD protection device of claim 1 also comprising:
at least a doped region positioned in the substrate and beyond the Zener diode;
at least a power line positioned on the dielectric layer of the semiconductor wafer; and
at least a second contact plug electrically connecting the doped region and the power line.

3. The ESD protection device of claim 1 wherein the Zener diode is a stacked structure comprising an N-type doped region and a P-type doped region.

4. The ESD protection device of claim 3 wherein the substrate is a P-type silicon substrate.

5. The ESD protection device of claim 3 wherein the substrate is a P well.

6. The ESD protection device of claim 1 wherein the Zener diode is a stacked structure comprising a P-type doped region and an N-type doped region.

7. The ESD protection device of claim 6 wherein the substrate is an N-type silicon substrate.

8. The ESD protection device of claim 6 wherein the substrate is an N well.

9. The ESD protection device of claim 1 wherein the Zener diode is a stacked structure comprising a P-type doped region and an N-type doped region, and dopant dosages of the P-type doped region and the N-type doped region both range from 1E13 to 1E14 cm⁻².

10. An electrostatic discharge (ESD) protection device comprising:
a Zener diode positioned in a substrate of a semiconductor wafer; and
a pad metal positioned above the Zener diode and electrically connected with the Zener diode.

11. The ESD protection device of claim 10 also comprising:
a dielectric layer positioned on the substrate;
at least a first contact plug positioned in the dielectric layer and electrically connecting the pad metal and the Zener diode; and
a passivation layer covering a surface of the semiconductor wafer and exposing a portion of a surface of the metal pad;
wherein the substrate is grounded for releasing electrostatic pulses accepted by the pad metal.

12. The ESD protection device of claim 11 also comprising:
at least a doped region positioned in the substrate and beyond the Zener diode;
at least a power line positioned on the dielectric layer of the semiconductor wafer; and
at least a second contact plug electrically connecting the doped region and the power line;
wherein the power line is used for sinking electric current of electrostatic pulses accepted by the pad metal.

13. The ESD protection device of claim 10 wherein the Zener diode is a stacked structure comprising an N-type doped region and a P-type doped region.

14. The ESD protection device of claim 13 wherein the substrate is a P-type silicon substrate.

15. The ESD protection device of claim 13 wherein the substrate is a P well.

16. The ESD protection device of claim 10 wherein the Zener diode is a stacked structure comprising a P-type doped region and an N-type doped region.

17. The ESD protection device of claim 16 wherein the substrate is an N-type silicon substrate.

18. The ESD protection device of claim 16 wherein the substrate is an N well.

19. The ESD protection device of claim 10 wherein the Zener diode is a stacked structure comprising a P-type doped region and an N-type doped region, and the dopant dosages of the P-type doped region and the N-type doped region both range from 1E13 to 1E14 cm⁻².
